(19) United States
(12) Patent Application Publication
(10) Pub. No.: US 2007/0108492 A1
(43) Pub. Date: May 17, 2007

(54) Semiconductor device and method for producing the same

(76) Inventor: Yoshiyuki Shibata, Shiga (JP)

Correspondence Address: MCDERMOTT WILL & EMERY LLP, 600 13TH STREET, N.W., WASHINGTON, DC, 20005-3096, US

(21) Appl. No.: 11/546,349

(22) Filed: Oct. 12, 2006

(30) Foreign Application Priority Data
Nov. 16, 2005 (JP) 2005-332106

(51) Int. Cl. H01L 27/108

(52) U.S. Cl. 257/303

(57) ABSTRACT

A semiconductor device including a lower electrode formed in a groove portion, a capacitor insulating film provided so as to cover the lower electrode, and an upper electrode provided so as to cover a plurality of lower electrodes with the capacitor insulating film, wherein a stress buffering portion, being an opening, is formed in the upper electrode. The opening, being the stress buffering portion, is formed by performing an etching process with a mask formed on the upper electrode.

### BACKGROUND OF THE INVENTION

The present invention relates to a semiconductor device having a capacitor and a method for producing the same and, more particularly, to a semiconductor device having a concave-shaped DRAM capacitor and a method for producing the same.

In recent years, there has been a demand to further reduce the size of DRAMs. Attention has been drawn to an approach using a metal oxide film having a high dielectric constant, particularly a TaOₓ film, for a capacitor insulating film of a capacitor section of DRAMs in order to ensure a sufficient charge-holding characteristic (see, for example, Japanese Laid-Open Patent Publication No. 11-026712).

Where a TaOₓ film is used as a capacitor insulating film and a material whose main component is Si as a lower electrode, it is possible to ensure a relative dielectric constant of 15 to 20. In contrast, where a TaOₓ film is used as a capacitor insulating film and a metal film as a lower electrode, it is possible to ensure a relative dielectric constant as high as 50 at maximum. Thus, where a TaOₓ film is used as a capacitor insulating film, it is possible to ensure a capacitance per unit capacitor area that is greater than or equal to three times as much as that where a SiO₂ film or an ON film (a layered film including a SiO₂ film and a SiNₓ film) is used as a capacitor insulating film.

Moreover, a TaOₓ film can be deposited by a thermal CVD process in a low-temperature range of 400° C. to 500° C., and is therefore considered to be advantageous in that it is possible to reduce the thermal damage to other elements.

Where a TaOₓ film is used as a capacitor insulating film, an upper electrode is typically a TiN film, which can be formed by depositing a material not containing an organic substance, which deteriorates the characteristics of the capacitor insulating film. Normally, a TiN film is deposited by a thermal CVD process using a material whose main components are TiCl₄ and NH₃. A TiN film can also be deposited in a low temperature range of 400° C. to 600° C. Therefore, the formation of a TiN film will not deteriorate the characteristics of a TaOₓ film being a capacitor insulating film or those of other elements such as transistors.

### SUMMARY OF THE INVENTION

However, with a DRAM capacitor having a capacitor insulating film being a TaOₓ film and an upper electrode being a TiN film, there is a problem in that the stress occurring in the TiN film acts upon the TaOₓ film. This will now be described more specifically with reference to the drawings. FIG. 6A is a cross-sectional view schematically showing a structure of a conventional DRAM capacitor.

Referring to FIG. 6A, a conventional DRAM capacitor 100 includes a first interlayer insulating film 101, a plurality of groove portions 102 formed in the first interlayer insulating film 101, a lower electrode 103 being a silicon film provided on the surface of each groove portion 102, a capacitor insulating film 104 being a TaOₓ film provided on the surface of the lower electrode 103, an upper electrode 105 being a TiN film provided so as to cover the capacitor insulating film 104, and a second interlayer insulating film 106 provided so as to cover the upper electrode 105. The capacitor insulating film 104 and the upper electrode 105 are provided so as to extend across the surface of each groove portion 102 and the upper surface of the first interlayer insulating film 101 outside the groove portion 102.

FIG. 6B is a cross-sectional view showing, on an enlarged scale, a portion of the structure shown in FIG. 6A where the capacitor insulating film 104 and the upper electrode 105 are layered together on the first interlayer insulating film 101 (a portion encircled by a one-dot chain line in FIG. 6A). As shown in FIG. 6B, the first interlayer insulating film 101, the capacitor insulating film 104 and the upper electrode 105 are layered together while being in contact with one another.

FIG. 6C is a plan view schematically showing a structure of a DRAM array area where a plurality of DRAM capacitors 100 are arranged in a pattern. As shown in FIG. 6C, the DRAM capacitors 100 are arranged in rows and columns, forming a matrix pattern. For example, one array may include some tens of thousands to one billion DRAM capacitors arranged therein. In such a structure, the upper electrode 105 is formed over a large area, covering the groove portions 102. Such a large upper electrode 105 itself has a large stress, thus resulting in a problem that the stress is localized at a particular DRAM capacitor.

FIG. 6D shows how a stress acts upon the DRAM capacitor 100 and the vicinity thereof. As shown in FIG. 6D, a stress is particularly localized in a portion of the upper electrode 105 above the first interlayer insulating film 101 outside the groove portion 102. If this stress acts upon the capacitor insulating film 104, it deteriorates the leak current characteristic and the charge-holding characteristic of the capacitor insulating film 104. The deterioration of initial characteristics, such as the leak current characteristic and the charge-holding characteristic, lowers the long-term reliability, e.g., the likelihood of dielectric breakdown. The occurrence of such a stress is particularly significant when the thickness of the upper electrode is greater than or equal to 40 nm.

An object of the present invention is to suppress deterioration of a capacitor insulating film by providing means for reducing the stress occurring in the upper electrode of a DRAM capacitor.

A semiconductor device in one embodiment of the present invention is a semiconductor device including a capacitor, wherein the capacitor includes: a plurality of lower electrodes; a capacitor insulating film formed on each of the lower electrodes; and an upper electrode covering the lower electrodes, with the capacitor insulating film being sandwiched therebetween, the upper electrode having an opening being a stress buffering portion.

In the semiconductor device of the present invention, the stress occurring in the upper electrode is buffered by the stress buffering portion. Therefore, it is possible to reduce the amount of stress to be exerted from the upper electrode onto the capacitor insulating film. Thus, it is possible to desirably maintain the leak current characteristic and the charge-holding characteristic of the capacitor insulating film while suppressing the lowering of the long-term reliability.

A semiconductor device in one embodiment of the present invention further includes an insulating film including a plurality of grooves therein, wherein: each of the lower electrodes covers a surface of each of the grooves; and the upper electrode covers an upper surface of portions of the insulating film outside the grooves. In a concave-shaped capacitor, since a greater amount of stress occurs in the upper electrode as the area of the upper electrode increases, it is particularly effective to form a stress buffering portion.

In a semiconductor device in one embodiment of the present invention, it is preferred that the stress buffering portion is provided in portions of the upper electrode that cover the outside of the grooves. A stress is likely to be localized in portions of the upper electrode that cover the outside of the grooves, i.e., portions that cover the upper surface of the insulating film. Therefore, with the stress buffering portion provided in these portions, it is possible to effectively buffer the stress.

The capacitor insulating film may include TaOₓ, and the lower electrode may include TiN.

A method for producing a semiconductor device in one embodiment of the present invention is a method for producing a semiconductor device having a capacitor, including: a step (a) of forming a plurality of lower electrodes; a step (b) of forming a capacitor insulating film covering each of the lower electrodes; a step (c) of forming an upper electrode covering the lower electrodes, with the capacitor insulating film being sandwiched therebetween; and a step (d) of performing an etching process with a mask formed on the upper electrode so as to form an opening to be a stress buffering portion in the upper electrode.

In a semiconductor device formed by a production method in one embodiment of the present invention, the stress occurring in the upper electrode can be buffered by the stress buffering portion. Therefore, it is possible to reduce the amount of stress to be exerted from the upper electrode onto the capacitor insulating film. Thus, it is possible to desirably maintain the leak current characteristic and the charge-holding characteristic of the capacitor insulating film while suppressing the lowering of the long-term reliability. In a production method in one embodiment of the present invention, an etching process is performed with a mask formed on the upper electrode. Therefore, it is possible to more reliably control the position and the size of the stress buffering portion.

A production method in one embodiment of the present invention further includes, before the step (a), a step of forming a plurality of grooves in an insulating film, wherein: in the step (a), each of the lower electrodes is formed on a surface of a corresponding one of the grooves; and in the step (c), the upper electrode is formed to cover an upper surface of portions of the insulating film outside the grooves. In the process of forming a concave-shaped capacitor, if an upper electrode having a large area is formed in the step (c), a large amount of stress may occur in the upper electrode. Thus, if the stress buffering portion is formed in the upper electrode simultaneously with the formation of the upper electrode, as in the present invention, it is possible to effectively suppress the occurrence of the stress.

The production method in one embodiment of the present invention may further include, after the step (d), a step of removing the mask.

### BRIEF DESCRIPTION OF THE DRAWINGS

FIGS. 1A to 1D are diagrams schematically showing a structure of a semiconductor device according to a first embodiment of the present invention.

FIGS. 2A to 2F are cross-sectional views showing a method for producing a semiconductor device according to a second embodiment of the present invention.

FIGS. 3A to 3C are cross-sectional views showing the method for producing a semiconductor device according to the second embodiment of the present invention.

FIG. 4 is a graph showing the relationship between the thickness of a TiN film and the stress occurring in the film.

FIG. 5A is a cross-sectional view showing a structure where a DRAM capacitor is provided over a transfer gate, and FIG. 5B is a cross-sectional view showing a structure where a DRAM capacitor is provided directly on a semiconductor substrate.

FIGS. 6A to 6D are diagrams schematically showing a structure of a conventional DRAM capacitor.

### DESCRIPTION OF THE PREFERRED EMBODIMENTS

### First Embodiment

A semiconductor device according to a first embodiment of the present invention will now be described with reference to the drawings.

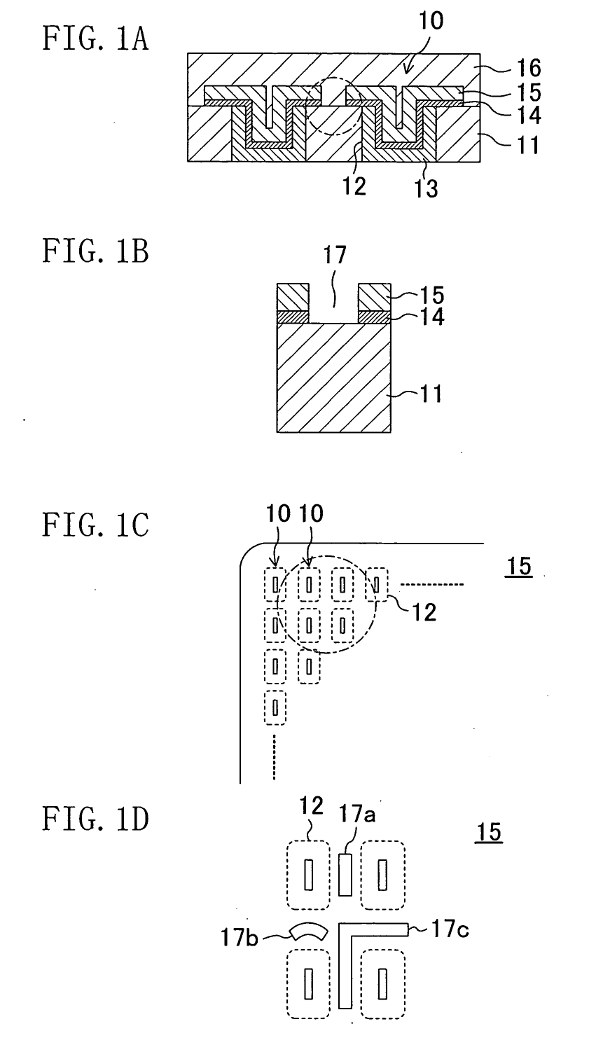

FIG. 1A is a cross-sectional view schematically showing a structure of a semiconductor device according to the first embodiment of the present invention. Referring to FIG. 1A, a DRAM capacitor 10 of the present embodiment includes a first interlayer insulating film 11, a plurality of groove portions 12 formed in the first interlayer insulating film 11, a lower electrode 13 being a silicon film provided on the surface of each groove portion 12, a capacitor insulating film 14 being a TaOₓ film provided on the surface of the lower electrode 13, an upper electrode 15 being a TiN film provided so as to cover the capacitor insulating film 14, and a second interlayer insulating film 16 provided so as to cover the upper electrode 15. The capacitor insulating film 14 and the upper electrode 15 are provided so as to extend across the surface of each groove portion 12 and the upper surface of the first interlayer insulating film 11 outside the groove portion 12.

FIG. 1B is a cross-sectional view showing, on an enlarged scale, a portion of the structure shown in FIG. 1A where the capacitor insulating film 14 and the upper electrode 15 are layered together on the first interlayer insulating film 11 (a portion encircled by a one-dot chain line in FIG. 1A). As shown in FIG. 1B, the first interlayer insulating film 11, the capacitor insulating film 14 and the upper electrode 15 are layered together while being in contact with one another. A stress buffering portion 17 is provided in the upper electrode 15. The stress buffering portion 17 is an opening (an open pattern) provided in the upper electrode 15. The stress buffering portion 17 may or may not be running through the upper electrode 15 and the capacitor insulating film 14. For example, the opening of the stress buffering portion 17 may be provided only in a surface portion of the upper electrode 15. While the width of the opening is constant in the stress buffering portion 17 shown in FIG. 1B, the width of the opening do not have to be constant. For example, the width of the opening may gradually increase or decrease in the depth direction.

FIG. 1C is a plan view schematically showing a structure of a DRAM array area where a plurality of DRAM capacitors 10 are arranged in a pattern. As shown in FIG. 1C, the DRAM capacitors 10 are arranged in rows and columns, forming a matrix pattern. For example, one array may include some tens of thousands to one billion DRAM capacitors arranged therein. In such a structure, the upper electrode 15 is formed over a large area, covering the groove portions 12. While the stress buffering portion 17 is formed in the area shown in FIG. 1C, it is not shown in the figure.

FIG. 1D is a plan view schematically showing an exemplary pattern of stress buffering portions. As shown in FIG. 1D, the DRAM array area of the present embodiment includes stress buffering portions 17a to 17c is formed in portions of the upper electrode 15 that are located outside the groove portion 12 above the first interlayer insulating film 11 (shown in FIG. 1A). The surface shape of the stress buffering portion 17a is straight, and that of the stress buffering portion 17b is curved. The surface shape of the stress buffering portion 17c is bent. The surface shape of the stress buffering portion 17 does not need to be an elongate shape, as are those of the stress buffering portions 17a to 17c, but may be polygonal or circular. The opening to be the stress buffering portion 17 does not overlap with the groove portion 12 where the lower electrode 13 is formed.

In the present embodiment, the stress occurring in the upper electrode 15 is buffered by the stress buffering portion 17, thereby reducing the amount of stress to be exerted from the upper electrode 15 onto the capacitor insulating film 14. Thus, it is possible to suppress the leak current flowing through the capacitor insulating film 14, and it is possible to reliably hold the charge. Moreover, it is possible to suppress the lowering of the long-term reliability.

In the description above, the stress buffering portion 17 is formed outside the groove portion 12. However, in the present embodiment, the stress buffering portion 17 is formed inside the groove portion 12, i.e., in an area where the upper electrode 15, the capacitor insulating film 14 and the lower electrode 13 together form a capacitor. In such a case, it is preferred that the stress buffering portion 17 does not reach the capacitor insulating film 14.

### Second Embodiment

A method for producing a semiconductor device according to a second embodiment of the present invention will now be described with reference to the drawings. The present embodiment is directed to a method for forming a semiconductor device as set forth above in the first embodiment.

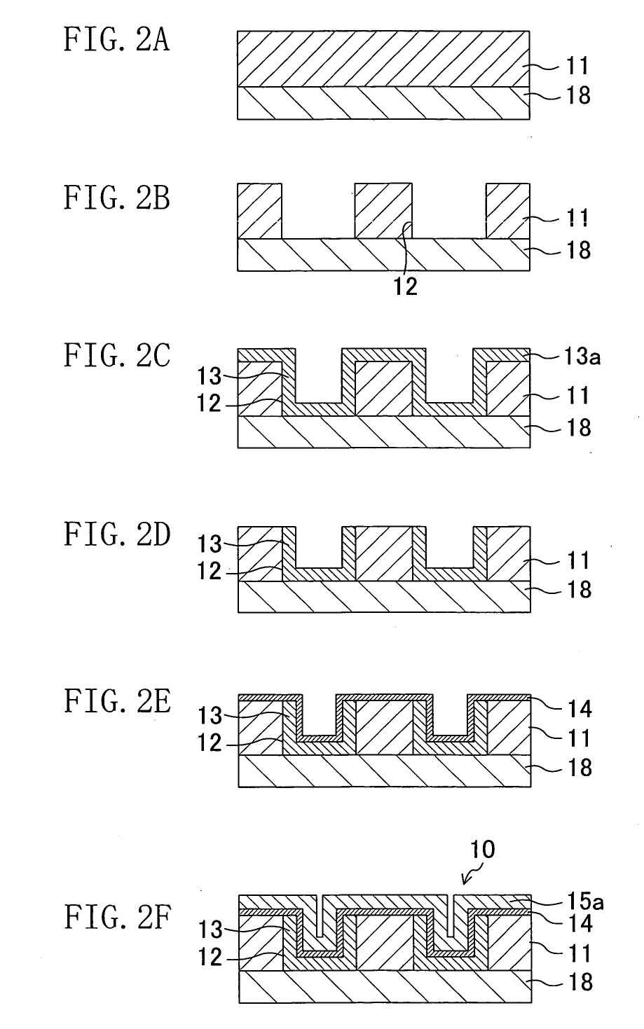

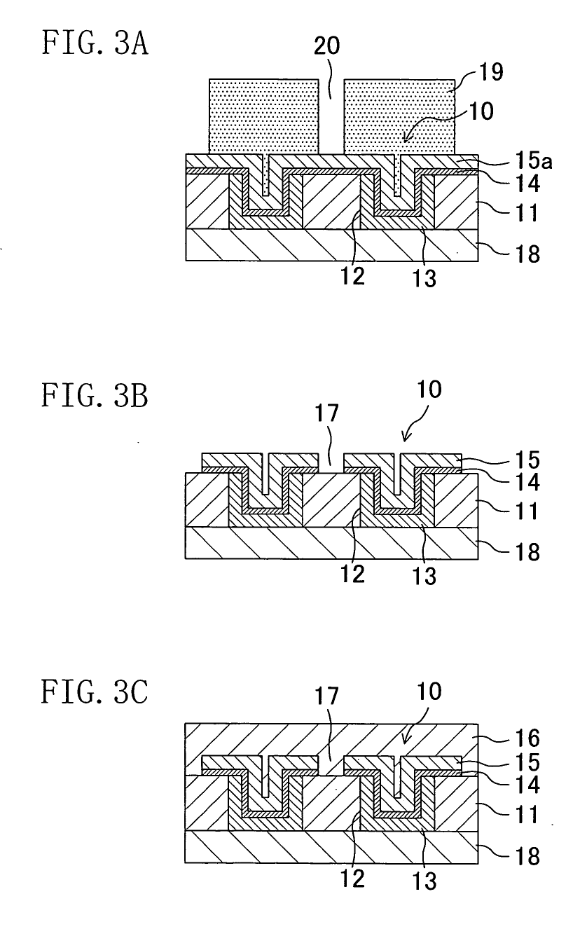

FIGS. 2A to 2F and 3A to 3C are cross-sectional views showing the method for producing a semiconductor device of the second embodiment. First, in the step shown in FIG. 2A of the production method of the present embodiment, the first interlayer insulating film 11 being a silicon oxide film having a thickness of 500 nm, for example, is formed on a base 18 being a semiconductor substrate, or the like.

Then, in the step shown in FIG. 2B, a resist mask (not shown) is formed on the first interlayer insulating film 11 by a photolithography method and the structure is dry-etched so as to form the groove portions 12 each having a size of 0.2 μm (minor side) by 0.4 μm (major side), for example, and running through the first interlayer insulating film 11 to reach the base 18.

Then, in the step shown in FIG. 2C, a silicon film 13a having a thickness of 300 nm, for example, is formed by a CVD process so as to cover the surface of each groove portion 12 and to cover the surface of the first interlayer insulating film 11 outside the groove portion 12.

Then, in the step shown in FIG. 2D, a resist mask (not shown) is formed on the silicon film 13a by a photolithography method so as to fill the groove portions 12 while exposing the area between the groove portions 12. Then, the structure is dry-etched with the resist mask thereon so as to remove exposed portions of the silicon film 13a, thus forming the lower electrode 13 in each groove portion 12.

Then, in the step shown in FIG. 2E, a thermal CVD process is performed at a temperature of 450° C. to form the capacitor insulating film 14 being a TaOₓ film having a thickness of 10 nm, for example, covering the lower electrode 13 in each groove portion 12 and the first interlayer insulating film 11 outside the groove portion 12.

Then, in the step shown in FIG. 2F, a CVD process is performed while supplying a material whose main components are TiCl₄ and NH₃ so as to form a TiN film 15a, to be the upper electrode 15, on the capacitor insulating film 14. While a TiN film as an upper electrode typically needs a thickness of only about 30 nm, a TiN film having a thickness of 40 nm or more may be formed in the present embodiment.

Then, in the step shown in FIG. 3A, a resist mask 19 is formed on the TiN film 15a by a photolithography method. Then, the structure is dry-etched so as to remove unnecessary portions of the resist mask 19 and form an opening 20 in the resist mask 19. The opening 20 is for providing the stress buffering portion 17.

Then, in the step shown in FIG. 3B, the structure is dry-etched while using the resist mask 19 as an etching mask so as to remove unnecessary portions of the TiN film 15a and form the stress buffering portion 17. This yields the upper electrode 15 that covers the inside of the groove portion 12 and covers a portion of the first interlayer insulating film 11 between the groove portions 12. The stress buffering portion 17 may or may not be running through the TiN film 15a and the capacitor insulating film 14.

Then, in the step shown in FIG. 3C, the second interlayer insulating film 16, whose thickness outside the groove portion 12 is 300 nm, is formed on the upper electrode 15. Then, contact plugs and wires (not shown) are formed to run through the second interlayer insulating film 16. Through these steps described above, the semiconductor device of the present embodiment is provided.

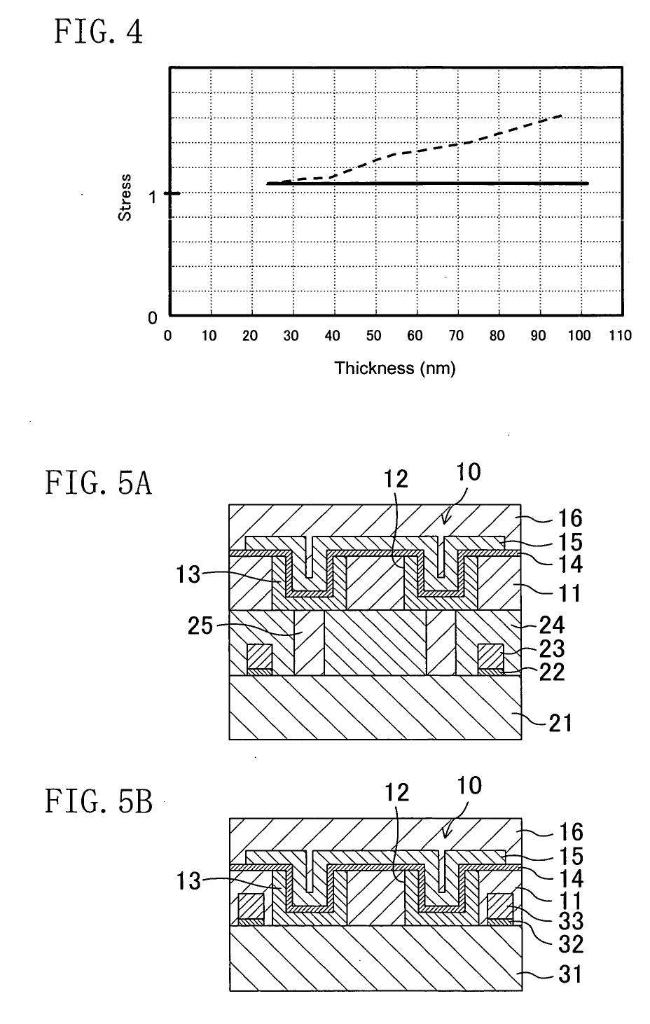

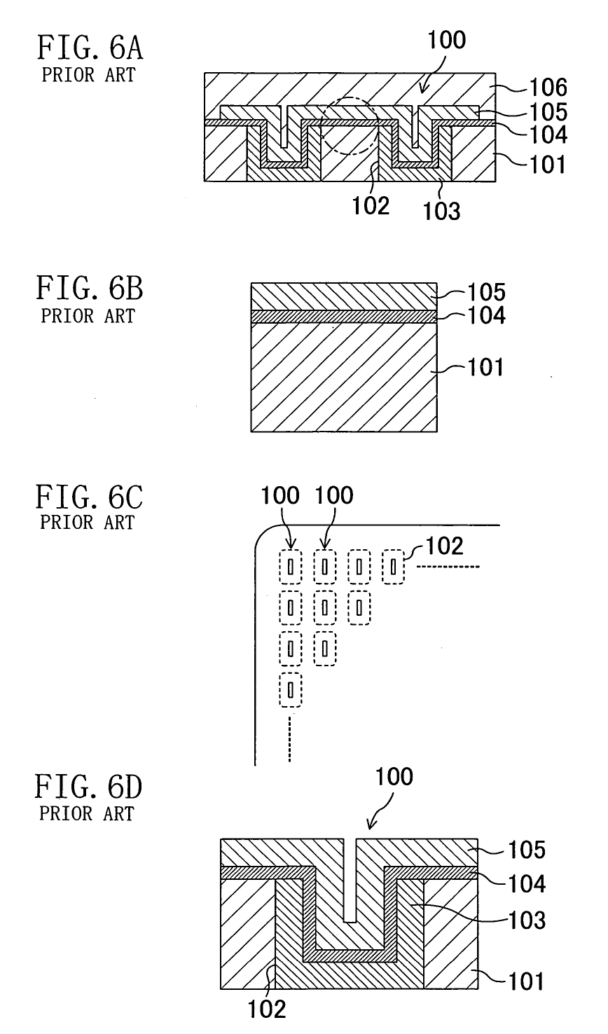

FIG. 4 is a graph showing the relationship between the thickness of the upper electrode being a TiN film and the stress occurring in the film. In FIG. 4, the horizontal axis represents the thickness of the TiN film, and the vertical axis represents the magnitude (relative value) of the stress occurring in the TiN film. In FIG. 4, the profile shown in a solid line represents the stress expected to occur in the semiconductor device of the present embodiment, and that shown in a broken line represents the stress expected to occur in a semiconductor device without a stress buffering portion.

As shown in FIG. 4, a semiconductor device without a stress buffering portion is expected to undergo a stress that does not change substantially for TiN film thickness values up to about 30 nm but increases for TiN film thickness values of 30 nm or more. In contrast, the semiconductor device of the present embodiment is expected to undergo a constant stress, independently of the thickness.

With a semiconductor device formed by the method of the present embodiment, the stress occurring in the upper electrode 15 can be buffered by the stress buffering portion 17. Therefore, it is possible to reduce the amount of stress to be exerted from the upper electrode 15 onto the capacitor insulating film 14. Thus, it is possible to desirably maintain the leak current characteristic and the charge-holding characteristic of the capacitor insulating film 14 while suppressing the lowering of the long-term reliability. Where the stress buffering portion 17 is formed by etching the structure with a resist mask formed on the TiN film 15a, as in the production method of the present embodiment, it is possible to more accurately control the position and the size of the stress buffering portion 17.

### Other Embodiments

While the above embodiments are directed to cases where the lower electrode 13 is a silicon film, similar effects can be obtained in the present invention also in cases where the lower electrode 13 is a metal film or a TiN film.

While the above embodiments are directed to cases where the capacitor insulating film 14 is made of TaOₓ and the upper electrode 15 is made of TiN, other materials may be employed in the present invention for the capacitor insulating film 14 and the upper electrode 15. For example, the capacitor insulating film 14 may be made of alumina or HfO₂, and the upper electrode 15 may be made of Pt, WN, TaN, TiAIN, TiSiN or RuO.

A step of roughening the surface of the silicon film 13a may be added after the step shown in FIG. 2C in the second embodiment, or a step of roughening the surface of the lower electrode 13 may be added after the step shown in FIG. 2D.

Phosphorus (P) may be introduced while performing a heat treatment to the silicon film 13a after the step shown in FIG. 2C in the second embodiment, or phosphorus may be introduced while performing a heat treatment to the lower electrode 13 after the step shown in FIG. 2D.

A step of nitriding the surface of the lower electrode 13, for example, may be added after the step shown in FIG. 2D in the second embodiment and before the step shown in FIG. 2E.

The DRAM capacitor of the above embodiments may be provided in an area as shown in FIG. 5A or 5B.

FIG. 5A is a cross-sectional view showing a structure where the DRAM capacitor is provided over a transfer gate. In the structure shown in FIG. 5A, a gate insulating film 22 and a gate electrode 23 are provided on a semiconductor substrate 21, with an interlayer insulating film 24 formed on the semiconductor substrate 21 so as to cover the gate insulating film 22 and the gate electrode 23. A metal plug 25 is provided in the interlayer insulating film 24 so as to reach the semiconductor substrate 21. The first interlayer insulating film 11 as described above in the above embodiments is provided on the interlayer insulating film 24. The groove portions 12 are provided in the first interlayer insulating film 11, and the metal plug 25 is exposed on the bottom surface of each groove portion 12. The DRAM capacitor 10 is formed in each groove portion 12 provided in the first interlayer insulating film 11, and the lower electrode 13 of the DRAM capacitor 10 and the semiconductor substrate 21 are electrically connected to each other via the metal plug 25. The structure of the DRAM capacitor 10 itself is as described in the above embodiments, and will not be further described below.

FIG. 5B is a cross-sectional view showing a structure where the DRAM capacitor is provided directly on the semiconductor substrate. In the structure shown in FIG. 5B, a gate insulating film 32 and a gate electrode 33 are formed on a semiconductor substrate 31, with the first interlayer insulating film 11 formed on the semiconductor substrate 31 so as to cover the gate insulating film 32 and the gate electrode 33. The groove portions 12 are provided in the first interlayer insulating film 11 in areas other than those where the first interlayer insulating film 11 is covering the gate insulating film 32 and the gate electrode 33. The semiconductor substrate 31 is exposed on the bottom surface of each groove portion 12. The DRAM capacitor 10 is formed in each groove portion 12, and the lower electrode 13 of the DRAM capacitor 10 and the semiconductor substrate 31 are connected directly to each other. The structure of the DRAM capacitor 10 itself is as described in the above embodiments, and will not be further described below.

While the above embodiments are directed to a DRAM capacitor, the present invention is applicable also to other types of capacitors.

What is claimed is:

1. A semiconductor device, comprising a capacitor, wherein the capacitor comprises:
a plurality of lower electrodes;
a capacitor insulating film formed on each of the lower electrodes; and
an upper electrode covering the lower electrodes, with the capacitor insulating film being sandwiched therebetween, the upper electrode having an opening being a stress buffering portion.

2. The semiconductor device of claim 1, further comprising an insulating film including a plurality of grooves therein, wherein:
each of the lower electrodes covers a surface of each of the grooves; and
the upper electrode covers an upper surface of portions of the insulating film outside the grooves.

3. The semiconductor device of claim 2, wherein the stress buffering portion is provided in portions of the upper electrode that cover the outside of the grooves.

4. The semiconductor device of claim 1, wherein the capacitor insulating film includes TaOₓ, and the lower electrode includes TiN.

5. A method for producing a semiconductor device having a capacitor, comprising:
a step (a) of forming a plurality of lower electrodes;
a step (b) of forming a capacitor insulating film covering each of the lower electrodes;
a step (c) of forming an upper electrode covering the lower electrodes, with the capacitor insulating film being sandwiched therebetween; and
a step (d) of performing an etching process with a mask formed on the upper electrode so as to form an opening to be a stress buffering portion in the upper electrode.

6. The method for producing a semiconductor device of claim 5, further comprising, before the step (a), a step of forming a plurality of grooves in an insulating film, wherein:
in the step (a), each of the lower electrodes is formed on a surface of a corresponding one of the grooves; and
in the step (c), the upper electrode is formed to cover an upper surface of portions of the insulating film outside the grooves.

7. The method for producing a semiconductor device of claim 5, further comprising, after the step (d), a step of removing the mask
